(19) United States
(12) Patent Application Publication
(10) Pub. No.: US 2017/0233609 A1
(43) Pub. Date: Aug. 17, 2017

(54) RESIN COMPOSITION AND FIXING METHOD FOR PLATE-SHAPED WORKPIECE

(71) Applicant: DISCO CORPORATION, Tokyo (JP)

(72) Inventors: Seiji Harada, Tokyo (JP); Makoto Shimotani, Tokyo (JP)

(21) Appl. No.: 15/423,774

(22) Filed: Feb. 3, 2017

(30) Foreign Application Priority Data
Feb. 12, 2016 (JP) 2016-024815

(51) Int. Cl. C09J 4/00; H01L 23/00; B32B 9/00; B32B 37/12; C09J 5/00; B32B 7/12

(52) U.S. Cl. CPC C09J 4/00; C09J 5/00; B32B 7/12; B32B 9/00; B32B 37/12; H01L 24/94; H01L 24/27; C09J 2433/00; C09J 2205/31; B32B 2037/1253; B32B 2307/20; B32B 2310/0837; B32B 2313/00; B32B 2333/12; B32B 2457/14

(57) ABSTRACT

Disclosed herein is a resin composition for fixing a plate-shaped workpiece. The resin composition includes a composition and a photopolymerization initiator added to the composition. This composition is composed of (meth)acrylate and a plasticizer or a reactive diluent. Preferably, the composition constituting the resin composition contains 30% to 45% by mass of (meth)acrylate having an urethane bond, 5% to 15% by mass of (meth)acrylate not having an urethane bond, and 40% to 65% by mass of plasticizer, which is an ester.

### BACKGROUND OF THE INVENTION

Field of the Invention

The present invention relates to a resin composition for fixing a plate-shaped workpiece such as a wafer, and also to a fixing method of fixing the plate-shaped workpiece by using the resin composition.

Description of the Related Art

A wafer as the material of semiconductor devices (devices) is usually obtained by cutting an ingot formed of a semiconductor such as silicon, silicon carbide, and gallium nitride with a tool such as band saw and wire saw. Such a wafer (as-sliced wafer) just after cutting has warpage or waviness. To remove such warpage or waviness, there has been proposed a processing method including the steps of applying a resin to one side of such a wafer, next curing this resin applied to one side of the wafer, and next grinding the other side of the wafer to remove the warpage or waviness and thereby flatten the wafer (see Japanese Patent Laid-open No. 2009-148866, for example).

### SUMMARY OF THE INVENTION

In general, a resin containing a liquid such as water and solvent has a property such that when the liquid is volatilized, the resin shrinks. Further, in a curing resin curable by light or heat, the resin changes in volume due to curing and it is accordingly prone to shrink. In the case that a resin showing high shrinkage in curing is used to fix a plate-shaped workpiece such as a wafer, a stress is generated in the plate-shaped workpiece due to the shrinkage of the resin.

If the plate-shaped workpiece is ground to be flattened in the condition where such an internal stress is present in the plate-shaped workpiece, the internal stress is relieved in removing the resin from the plate-shaped workpiece, so that warpage or waviness may appear again (so-called spring back). This problem may be solved by using a resin showing sufficiently low shrinkage in curing to thereby reduce the force acting on the plate-shaped workpiece. However, such a resin showing low shrinkage is hard to cure and it is unsuitable for fixing of the plate-shaped workpiece. Furthermore, much time is required for the completion of curing of the resin, causing a reduction in productivity.

It is therefore an object of the present invention to provide a resin composition which can reduce a stress generated in a plate-shaped workpiece in fixing the plate-shaped workpiece and can also maintain high productivity.

It is another object of the present invention to provide a fixing method of fixing the plate-shaped workpiece by using the resin composition.

In accordance with an aspect of the present invention, there is provided a resin composition for fixing a plate-shaped workpiece, the resin composition including a composition and a photopolymerization initiator added to the composition, wherein the composition is composed of (meth)acrylate and a plasticizer or a reactive diluent.

With this configuration, the shrinkage of the resin composition in curing can be reduced by the plasticizer or the reactive diluent, so that it is possible to realize the resin composition which can be cured in a short time with the shrinkage suppressed. Accordingly, it is possible to obtain the resin composition which can reduce a stress generated in the plate-shaped workpiece in fixing the plate-shaped workpiece.

Preferably, the (meth)acrylate includes first (meth)acrylate having an urethane bond and second (meth)acrylate not having the urethane bond, and the composition contains 30% to 45% by mass of the first (meth)acrylate, 5% to 15% by mass of the second (meth)acrylate, and 40% to 65% by mass of the plasticizer. Preferably, the plasticizer is an ester. The (meth)acrylate having an urethane bond shows high curability and low shrinkage. The (meth)acrylate not having an urethane bond shows high curability and high shrinkage. The ester as the plasticizer shows low shrinkage. Thus, a plurality of materials are mixed in a proper proportion, so that it is possible to realize the resin composition which can be cured in a short time with the shrinkage suppressed. Accordingly, it is possible to obtain the resin composition which can reduce a stress generated in the plate-shaped workpiece in fixing the plate-shaped workpiece.

Preferably, the (meth)acrylate is (meth)acrylate having an urethane bond, and the composition contains 35% to 70% by mass of the (meth)acrylate having the urethane bond and 30% to 65% by mass of the reactive diluent. Preferably, the reactive diluent is an ether having a single epoxy group in a molecule.

With this configuration, the composition is composed by mixing the (meth)acrylate having an urethane bond and the reactive diluent having a single epoxy group in a molecule. Accordingly, the content of the (meth)acrylate having an urethane bond in this composition can be reduced. Further, since the reactive diluent has a single epoxy group in a molecule, the viscosity of the composition can be suppressed as compared with another compound having a plurality of epoxy groups in a molecule. Thus, by adding the reactive diluent, the viscosity of the composition can be reduced and the content of the (meth)acrylate having an urethane bond in the composition can be reduced. Accordingly, it is possible to realize the resin composition which can be cured in a short time with the shrinkage suppressed. Accordingly, it is possible to obtain the resin composition which can reduce a stress generated in the plate-shaped workpiece in fixing the plate-shaped workpiece.

In accordance with another aspect of the present invention, there is provided a fixing method of fixing a plate-shaped workpiece by using a resin composition including a composition and a photopolymerization initiator added to the composition, the composition being composed of (meth)acrylate and a plasticizer or a reactive diluent, the fixing method including a resin composition supplying step of supplying the resin composition between a stage and a first surface of the plate-shaped workpiece; a pressing step of applying a pressure to the plate-shaped workpiece in a direction from a second surface of the plate-shaped workpiece toward the first surface after performing the resin composition supplying step, thereby pressing the plate-shaped workpiece against the stage to uniformly spread the resin composition over the first surface of the plate-shaped workpiece; and a curing step of applying light to the resin composition after performing the pressing step, thereby curing the resin composition.

The resin composition to be used in the fixing method includes the composition and the photopolymerization initiator added thereto, wherein the composition is composed of the (meth)acrylate and the plasticizer or the reactive diluent. Accordingly, the shrinkage of the resin composition in curing can be reduced by the plasticizer or the reactive diluent, so that it is possible to realize the fixing method of fixing the plate-shaped workpiece by using the resin composition which can be cured in a short time with the shrinkage suppressed, thereby reducing a stress generated in the plate-shaped workpiece in fixing the plate-shaped workpiece and also maintaining high productivity.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a plate-shaped workpiece to be fixed by a resin composition according to a preferred embodiment of the present invention;

FIG. 2 is an enlarged sectional view of a part of the plate-shaped workpiece shown in FIG. 1;

FIG. 3 is a perspective view showing the configuration of a fixing apparatus for fixing the plate-shaped workpiece;

FIG. 4 is a partially sectional side view schematically showing a first step of a fixing method of fixing the plate-shaped workpiece by using the resin composition according to this preferred embodiment;

FIG. 5 is a view similar to FIG. 4, showing a second step of the fixing method;

FIG. 6 is a view similar to FIG. 4, showing a third step of the fixing method;

FIG. 7 is a view similar to FIG. 4, showing a fourth step of the fixing method;

FIG. 8 is a table obtained by summarizing the results of examples using a first preferred embodiment of the resin composition; and

FIG. 9 is a table obtained by summarizing the results of examples using a second preferred embodiment of the resin composition.

### DETAILED DESCRIPTION OF THE PREFERRED EMBODIMENTS

A preferred embodiment of the present invention will now be described in detail with reference to the drawings. The present invention is not limited to this preferred embodiment. Further, the components used in this preferred embodiment may include those that can be easily assumed by persons skilled in the art or substantially the same elements as those known in the art. Further, the configurations described below may be suitably combined. Further, the configurations may be variously omitted, replaced, or changed without departing from the scope of the present invention.

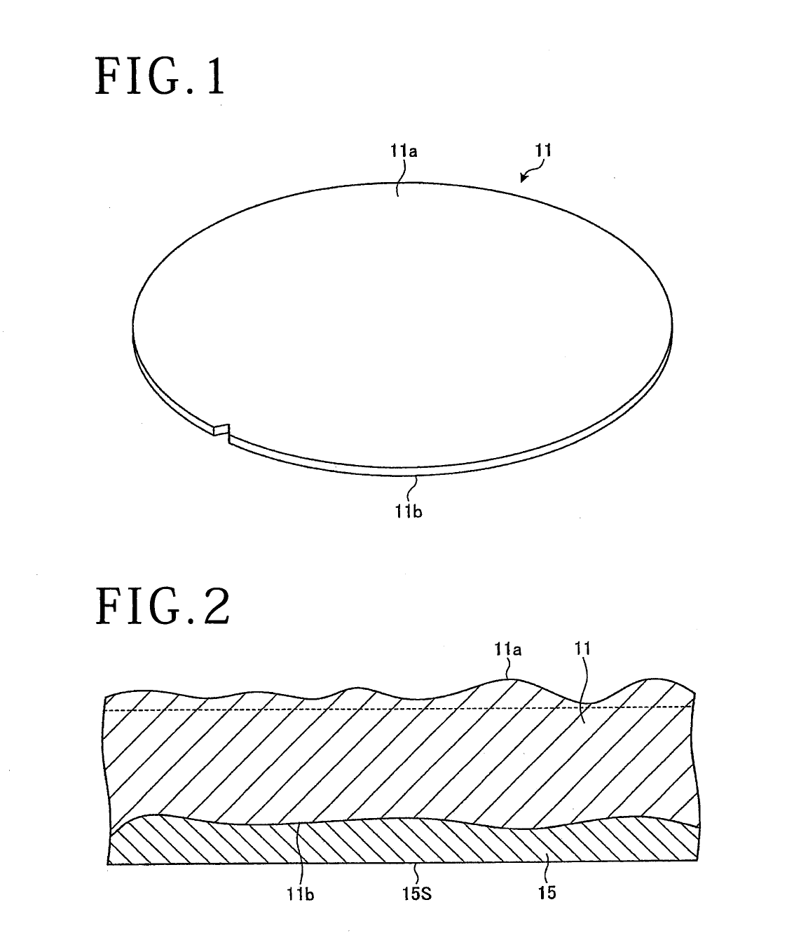

The resin composition according to this preferred embodiment is used for fixing of a plate-shaped workpiece such as wafer. FIG. 1 is a perspective view of a plate-shaped workpiece 11 to be fixed by the resin composition according to this preferred embodiment, and FIG. 2 is an enlarged sectional view of a part of the plate-shaped workpiece 11 shown in FIG. 1. As shown in FIG. 1, the plate-shaped workpiece 11 is a circular wafer (as-sliced wafer) obtained by cutting a cylindrical ingot with a tool such as band saw and wire saw. The ingot is formed of a semiconductor such as silicon, silicon carbide, and gallium nitride. As shown in FIG. 1, the plate-shaped workpiece 11 has warpage or waviness due to the cutting of the ingot. The plate-shaped workpiece 11 having such warpage or waviness is not suitable for the formation of devices. Accordingly, it is necessary to fix the plate-shaped workpiece 11 by using a resin composition and then flatten the plate-shaped workpiece 11. For example, as shown in FIG. 2, a resin composition 15 is applied to the back side (first surface) 11b of the plate-shaped workpiece 11 and then cured to form a flat reference surface 15S. Thereafter, the front side (second surface) 11a of the plate-shaped workpiece 11 is ground to thereby remove the warpage or waviness present on the front side (second surface) 11a of the plate-shaped workpiece 11.

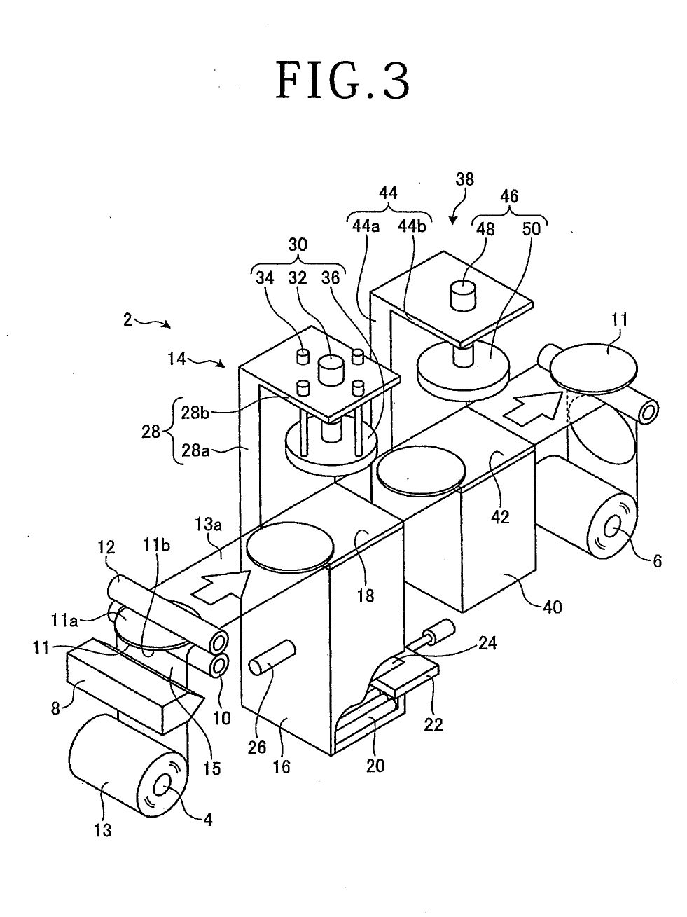

FIG. 3 is a perspective view showing the configuration of a fixing apparatus 2 for fixing the plate-shaped workpiece 11. As shown in FIG. 3, the fixing apparatus 2 includes a supply roller 4 on which a film 13 is rolled and a take-up roller 6 for taking up the film 13 supplied from the supply roller 4.

Each of the supply roller 4 and the take-up roller 6 is connected to a rotational drive source (not shown) such as a motor, thereby moving the film 13 from the supply roller 4 to the take-up roller 6. The film 13 is formed of a soft resin material such as polyolefin.

The fixing apparatus 2 includes a resin supply unit 8 such as a slit coater above the supply roller 4. The resin supply unit 8 functions to supply the resin composition 15 in a liquid state to the front side 13a of the film 13 supplied from the supply roller 4. The resin composition 15 will be hereinafter described in detail.

The fixing apparatus 2 includes a pair of rollers 10 and 12 above the resin supply unit 8. The roller 10 is a lower roller, and the roller 12 is an upper roller. These rollers 10 and 12 function to position the plate-shaped workpiece 11 on the front side 13a of the film 13 on which the resin composition 15 has been supplied. That is, the plate-shaped workpiece 11 is positioned through the resin composition 15 on the front side 13a of the film 13 by the rollers 10 and 12. The lower roller 10 functions to change the traveling direction of the film 13 and upward orient the front side 13a of the film 13 on which the resin composition 15 has been supplied.

Thus, the plate-shaped workpiece 11 is put on the front side 13a of the film 13 with the resin composition 15 interposed therebetween. While the back side 11b of the plate-shaped workpiece 11 comes into contact with the resin composition 15 in this preferred embodiment, the front side 11a of the plate-shaped workpiece 11 may come into contact with the resin composition 15. The upper roller 12 is rotated to abut against the plate-shaped workpiece 11 put on the film 13. The plate-shaped workpiece 11 put on the film 13 is sandwiched between the rollers 10 and 12 and then positioned on the film 13.

The fixing apparatus 2 includes a resin curing unit 14 adjacent to the rollers 10 and 12 on the downstream side thereof. The plate-shaped workpiece 11 positioned on the film 13 through the resin composition 15 by the rollers 10 and 12 is fed to the resin curing unit 14. The resin curing unit 14 includes a substantially boxlike base 16 having an inside space. A stage 18 having a substantially flat upper surface is provided at the upper portion of the base 16 so as to close the inside space of the base 16.

The stage 18 is formed of borosilicate glass or silica glass, for example. The stage 18 can transmit light having a wavelength curing the resin composition 15. The upper surface of the stage 18 is used as a holding surface for holding the film 13 fed from the rollers 10 and 12. The film 13 put on the stage 18 is held on the holding surface under suction by operating a suction mechanism (not shown) or the like.

A light source 20 for radiating light having a wavelength curing the resin composition 15 is provided below the stage 18. A shutter 22 for blocking the light from the light source 20 is provided between the stage 18 and the light source 20. Further, a filter 24 for blocking light having a wavelength unrequired for the curing of the resin composition 15 is provided just above the shutter 22.

Accordingly, when the shutter 22 is completely closed, the light from the light source 20 is blocked by the shutter 22 and does not reach the stage 18. On the other hand, when the shutter 22 is opened, the light from the light source 20 is transmitted through the filter 24 and the stage 18 and then applied to the film 13. The film 13 can transmit light having a wavelength curing the resin composition 15, so that the resin composition 15 is cured by the light transmitted through the film 13.

The base 16 has a side wall through which an evacuation pipe 26 extends into the inside space. The evacuation pipe 26 is connected to an evacuation pump (not shown) or the like provided outside the base 16. When the temperature inside the base 16 rises due to the light from the light source 20, the stage 18 may be deformed to cause a reduction in flatness of the holding surface. To cope with this problem, the inside space of the base 16 is evacuated through the evacuation pipe 26 by operating the evacuation pump, thereby suppressing a temperature rise inside the base 16.

A support structure 28 is provided adjacent to the stage 18 on the upper side thereof. The support structure 28 includes a wall portion 28a vertically extending from the upper end of the base 16 at its rear portion and an overhang portion 28b horizontally projecting from the upper end of the wall portion 28a to the front side above the stage 18. A pressing mechanism 30 for downward pressing the plate-shaped workpiece 11 positioned on the film 13 is provided at the central area of the overhang portion 28b located above the stage 18.

The pressing mechanism 30 includes a central main rod 32 extending vertically and a plurality of (four in this preferred embodiment) subrods 34 arranged parallel to the main rod 32. The plural subrods 34 are arranged around the main rod 32 at substantially equal intervals. A circular pressing pad 36 having a shape corresponding to the shape of the plate-shaped workpiece 11 is fixed to the lower ends of the main rod 32 and the plural subrods 34.

Each of the main rod 32 and the plural subrods 34 is connected to an elevating mechanism (not shown) including a motor or the like. When the elevating mechanism is operated to lower the main rod 32 and the plural subrods 34, the front side 11a of the plate-shaped workpiece 11 can be pressed by the pressing pad 36. The elevating mechanism can vertically move the main rod 32 and the plural subrods 34 independently to thereby adjust a pressure to be applied to the plate-shaped workpiece 11.

After setting the back side 11b of the plate-shaped workpiece 11 on the resin composition 15 applied to the film 13, the front side 11a of the plate-shaped workpiece 11 is pressed by operating the pressing mechanism 30 as mentioned above to thereby uniformly spread the resin composition 15 between the front side 13a of the film 13 and the back side 11b of the plate-shaped workpiece 11. Thereafter, the light from the light source 20 is applied to the resin composition 15 to thereby cure the resin composition 15. As a result, the plate-shaped workpiece 11 can be fixed to the film 13 by the resin composition 15.

The fixing apparatus 2 further includes a film cutting unit 38 adjacent to the resin curing unit 14 on the downstream side thereof. The plate-shaped workpiece 11 fixed by the resin composition 15 in the resin curing unit 14 is fed to the film cutting unit 38. The film cutting unit 38 includes a substantially boxlike base 40. A table 42 having a substantially flat upper surface is provided at the upper portion of the base 40. The upper surface of the table 42 is used as a holding surface for holding the film 13 fed from the resin curing unit 14.

A support structure 44 is provided adjacent to the table 42 on the upper side thereof. The support structure 44 includes a wall portion 44a vertically extending from the upper end of the base 40 at its rear portion and an overhang portion 44b horizontally projecting from the upper end of the wall portion 44a to the front side above the table 42. A cutting mechanism 46 for circularly cutting the film 13 is provided at the central area of the overhang portion 44b located above the table 42.

The cutting mechanism 46 includes a vertically extending rod 48 and a cutter 50 having a ringlike cutting blade larger in diameter than the plate-shaped workpiece 11. The cutter 50 is fixed to the lower end of the rod 48. An elevating mechanism (not shown) such as air cylinder is connected to the upper portion of the rod 48. Accordingly, the cutter 50 is vertically movable by the elevating mechanism. When the elevating mechanism is operated to lower the cutter 50, the cutter 50 comes into contact with the film 13 held on the table 42, so that the film 13 can be cut into a circular shape corresponding to the outside shape of the plate-shaped workpiece 11. Thereafter, the plate-shaped workpiece 11 fixed through the resin composition 15 to the film 13 in the fixing apparatus 2 as mentioned above is transferred to a grinding apparatus (not shown). In the grinding apparatus, the front side 11a of the plate-shaped workpiece 11 is ground. Thereafter, the resin composition 15 and the film 13 are removed.

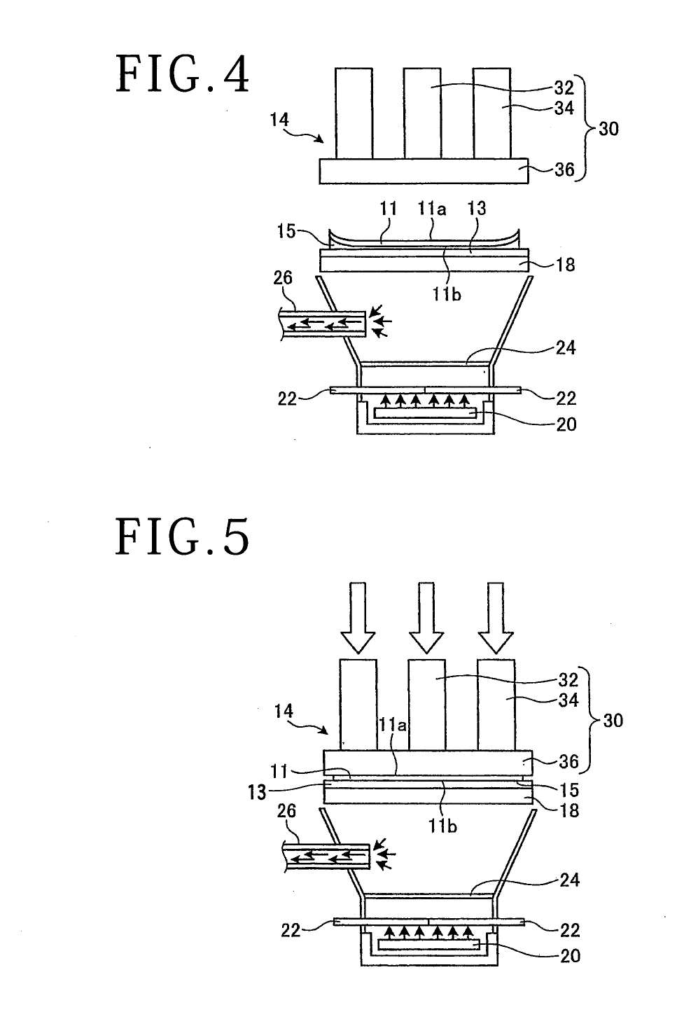

There will now be described a fixing method of fixing the plate-shaped workpiece 11 by using the resin composition 15 according to this preferred embodiment. FIGS. 4, 5, 6, and 7 are partially sectional side views schematically showing the fixing method of fixing the plate-shaped workpiece 11 by using the resin composition 15. In the fixing method according to this preferred embodiment, a resin composition supplying step (first step) is first performed in such a manner that the resin composition 15 is supplied between the stage 18 for holding the plate-shaped workpiece 11 and the back side (first surface) 11b of the plate-shaped workpiece 11. More specifically, as shown in FIG. 4, the back side 11b of the plate-shaped workpiece 11 is superimposed on the resin composition 15 in a liquid state supplied from the resin supply unit 8 to the film 13, and then fed to the upper surface of the stage 18 of the resin curing unit 14. At this time, the inside space of the base 16 is evacuated by the evacuation pump connected to the evacuation pipe 26, thereby suppressing a temperature rise inside the base 16. Further, the shutter 22 is closed in advance.

After performing the resin composition supplying step, a pressing step (second step) is performed in such a manner that the pressing pad 36 is lowered to downward press the front side (second surface) 11a of the plate-shaped workpiece 11 as shown in FIG. 5. In the pressing step, the plate-shaped workpiece 11 is positioned directly below the pressing mechanism 30, and the film 13 is held on the holding surface of the stage 18 under suction. In this condition, the pressing pad 36 is lowered to downward press the plate-shaped workpiece 11. As a result, the resin composition 15 in a liquid state is uniformly spread between the front side 13a (upper surface) of the film 13 and the back side 11b (lower surface) of the plate-shaped workpiece 11.

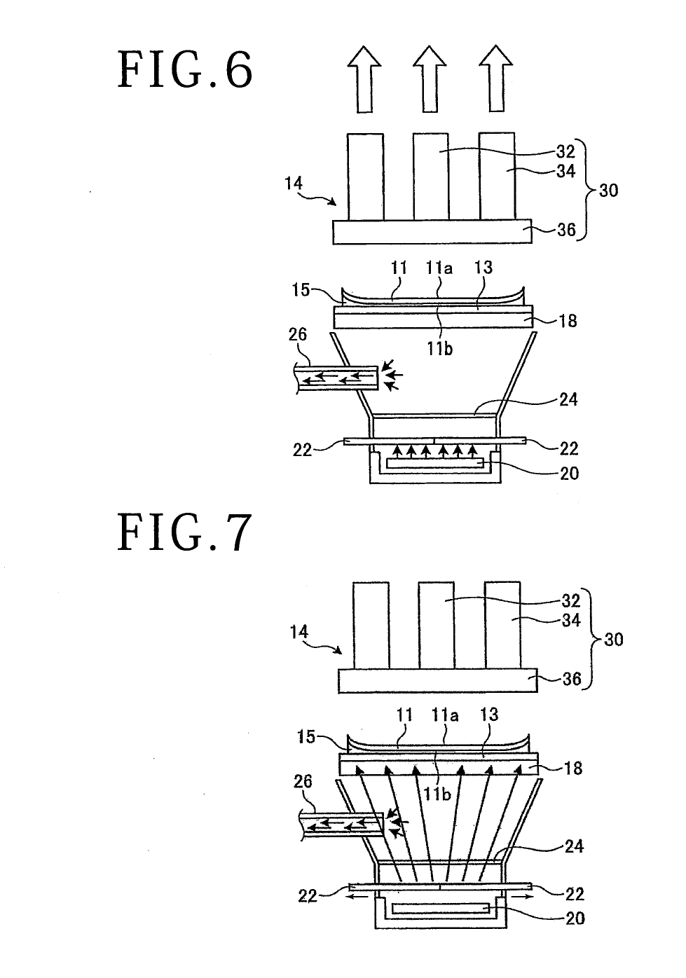

After uniformly spreading the resin composition 15 in a liquid state as mentioned above, the pressing pad 36 is raised to remove the pressure applied to the plate-shaped workpiece 11 as shown in FIG. 6 (third step). After performing the pressing step (the second and third steps), a curing step (fourth step) is performed in such a manner that light is applied to the resin composition 15 to thereby cure the resin composition 15. More specifically, as shown in FIG. 7, the shutter 22 is opened and the light source 20 is turned on to apply light (e.g., ultraviolet light) from the light source 20 to the resin composition 15. As a result, the resin composition 15 is cured to thereby fix the plate-shaped workpiece 11 through the resin composition 15 to the film 13.

The upper surface of the stage 18 for holding the resin composition 15 and the plate-shaped workpiece 11 is substantially flat, so that the lower surface (the reference surface 15S shown in FIG. 1) of the resin composition 15 kept in contact with the front side 13a (upper surface) of the film 13 held on the upper surface of the stage 18 is also substantially flat. After performing the curing step, a grinding step is performed to grind the front side (second surface) 11a of the plate-shaped workpiece 11 whose back side 11b is fixed to the resin composition 15. In performing the grinding step, the plate-shaped workpiece 11 fixed through the resin composition 15 to the film 13 is transferred to a grinding apparatus (not shown). Although not shown, the grinding apparatus includes a stage (chuck table) having a flat surface for holding the lower surface (the reference surface 15S) of the resin composition 15 fixing the plate-shaped workpiece 11 and a grinding mechanism movable both in a horizontal direction and in a vertical direction with respect to this stage. The plate-shaped workpiece 11 fixed through the resin composition 15 to the film 13 is placed on the flat surface of the stage of the grinding apparatus in the condition where the front side 11a of the plate-shaped workpiece 11 is exposed upward. In this condition, the front side (second surface) 11a of the plate-shaped workpiece 11 is ground by the grinding mechanism to thereby substantially flatten the front side 11a. After grinding the front side 11a of the plate-shaped workpiece 11, a removing step is performed to remove the resin composition 15 and the film 13 from the plate-shaped workpiece 11. A manufacturing method for the plate-shaped workpiece 11 is configured by adding to the fixing method mentioned above the grinding step of grinding the front side (second surface) 11a of the plate-shaped workpiece 11 and the removing step of removing the resin composition 15 and the film 13 from the plate-shaped workpiece 11.

In the fixing method for the plate-shaped workpiece 11 as mentioned above, the resin composition 15 in a liquid state is applied to the plate-shaped workpiece 11 and then cured to fix the plate-shaped workpiece 11. As a first preferred embodiment of the resin composition 15, a resin composition 15a is used in the present invention. Alternatively, as a second preferred embodiment of the resin composition 15, a resin composition 15b is used in the present invention. The resin composition 15a or 15b can be cured in a short time with the shrinkage suppressed, thereby realizing proper fixation of the plate-shaped workpiece 11. There will now be described the resin composition 15a as the first preferred embodiment and the resin composition 15b as the second preferred embodiment.

The resin composition 15a as the first preferred embodiment includes a composition and a photopolymerization initiator added to this composition in a predetermined proportion (e.g., 1% to 5%) to the whole amount of this composition, wherein this composition (which will be hereinafter referred to as composition A) is composed of (meth)acrylate having an urethane bond (urethane group), (meth)acrylate not having an urethane bond (urethane group), and a plasticizer. The content of the photopolymerization initiator is arbitrarily adjusted in such a range that curability of the resin composition 15a can be maintained.

The term of (meth)acrylate means acrylate as a compound of acrylic acid or methacrylate as a compound of methacrylic acid. The (meth)acrylate having an urethane bond (urethane group) has an urethane group in a molecule. Examples of the (meth)acrylate having an urethane bond include the following products, that is, Light acrylate IAA, AT-600, UA-306H, UA-306T, UA-306I, UA-510H, UF-8001G, DAUA-167, and UF-07DF (all manufactured by Kyoeisha Chemical Co., Ltd.); R-1235, R-1220, RST-201, RST-402, R-1301, R-1304, R-1214, R-1302XT, GX-8801A, R-1603, R-1150D, DOCR-102, and DOCR-206 (all manufactured by Dai-ichi Kogyo Seiyaku Co., Ltd.); and UX-3204, UX-4101, UXT-6100, UX-6101, UX-7101, UX-8101, UX-0937, UXF-4001-M35, UXF-4002, DPHA-40H, UX-5000, UX-5102D-M20, UX-5103D, UX-5005, UX-3204, UX-4101, UX-6101, UX-7101, UX-8101, UX-0937, UXF-4001-M35, UXF-4002, UXT-6100, DPHA-40H, UX-5000, UX-5102D-M20, UX-5103, and UX-5005 (all manufactured by Nippon Kayaku Co., Ltd.). In this preferred embodiment, UF-07DF (manufactured by Kyoeisha Chemical Co., Ltd.) is used as the (meth)acrylate having an urethane bond.

The (meth)acrylate not having an urethane bond does not have an urethane group in a molecule. Examples of the (meth)acrylate not having an urethane bond include tetrahydrofurfuryl acrylate, isobornyl acrylate, phenylglycidyl ether acrylate, and 1,9-nonane diol diacylate. In this preferred embodiment, tetrahydrofurfuryl acrylate or isobornyl acrylate is used as the (meth)acrylate not having an urethane bond.

The plasticizer is a material capable of entering the gap in the resin to hinder that the resin may be oriented regularly and maintain an amorphous state even at a glass transition point or lower. This plasticizer has a property such that it is hard to react with an acrylic group in the (meth)acrylate. Accordingly, in mixing the (meth)acrylate and the plasticizer to perform polymerization, the shrinkage of the resin composition 15a can be suppressed. Examples of the plasticizer used in this preferred embodiment include phthalic acid ester such as dimethyl phthalate and ethyl phthalyl ethyl glycolate, aliphatic dibasic acid ester such as bis[2-(2-butoxyethoxy) ethyl] adipate, sulfonamide such as N-butyl benzene sulfonamide, and benzoic acid glycol ester.

The photopolymerization initiator functions to initiate the photopolymerization of the composition A composed of the (meth)acrylate having an urethane bond (urethane group), the (meth)acrylate not having an urethane bond (urethane group), and the plasticizer, by applying light (e.g., ultraviolet light). In this preferred embodiment, 1-hydroxy cyclohexyl phenyl ketone (e.g., Irgacure (registered trademark) 184 etc. manufactured by BASF) is used as the photopolymerization initiator.

The composition A in the resin composition 15a of the first preferred embodiment contains 30% to 45% by mass of the (meth)acrylate having an urethane bond, 5% to 15% by mass of the (meth)acrylate not having an urethane bond, and 40% to 65% by mass of the plasticizer.

In general, the (meth)acrylate not having an urethane bond shows high curability, but also shows high shrinkage in curing. Accordingly, if the resin composition 15a is composed of only the (meth)acrylate not having an urethane bond, a large stress may be generated in the plate-shaped workpiece 11. To cope with this problem, the composition A contains the plasticizer showing low shrinkage to the (meth)acrylate not having an urethane bond and also showing low reactivity to the (meth)acrylate not having an urethane bond.

The plasticizer shows low curability, so that if the ratio of the (meth)acrylate not having an urethane bond to the plasticizer is too small, the resin composition 15a is hard to cure. However, if the ratio of the (meth)acrylate not having an urethane bond to the plasticizer is set to a ratio suitable for curing, the shrinkage cannot be sufficiently suppressed to cause a problem such that waviness or the like may be left on the plate-shaped workpiece 11. To cope with this problem, the composition A contains the (meth)acrylate having an urethane bond, which shows high curability and lower shrinkage as compared with the (meth)acrylate not having an urethane bond, in a predetermined proportion. Accordingly, the total content of (meth)acrylate is ensured and high curability and low shrinkage are maintained. As a result, the resin composition 15a can be cured in a short time with the shrinkage suppressed.

There will now be described examples of the composition A composed of the (meth)acrylate having an urethane bond, the (meth)acrylate not having an urethane bond, and the plasticizer, as prepared by making the content of each component different. That is, in the following examples, the content of each component of the composition A is changed to prepare a plurality of resin compositions.

### Example A1

In Example A1, a silicon wafer (as-sliced wafer) obtained by cutting an ingot was used as the plate-shaped workpiece 11. Further, the content of each component of the composition A was set to 50% by mass for the (meth)acrylate having an urethane bond, 20% by mass for the (meth)acrylate not having an urethane bond, and 30% by mass for the plasticizer. As the (meth)acrylate having an urethane bond, UF-07DF (manufactured by Kyoeisha Chemical Co., Ltd.) was used. As the (meth)acrylate not having an urethane bond, tetrahydrofurfuryl acrylate was used. As the plasticizer, benzoic acid glycol ester was used. Further, as the photopolymerization initiator, 1-hydroxy cyclohexyl phenyl ketone was used and it was added in a proportion of 1% by mass to the whole amount of the composition A.

The resin composition 15a prepared above was used to fix the plate-shaped workpiece (silicon wafer) 11 in the following fixing method. That is, ultraviolet light is applied to the resin composition 15a for a predetermined period of time (one minute), thereby curing the resin composition 15a. By using a surface defect inspecting apparatus “Makyo” (YIS-300SP manufactured by Yamashita Denso Corporation), the surface condition of the plate-shaped workpiece 11 fixed to the resin composition 15a was checked. Further, after grinding the front side (second surface) 11a of the plate-shaped workpiece 11 fixed to the resin composition 15a and next removing the plate-shaped workpiece 11 from the resin composition 15a, the amount of warpage of the plate-shaped workpiece 11 and the size of waviness on the plate-shaped workpiece 11 were observed.

The amount of warpage of the plate-shaped workpiece 11 was evaluated by using a flatness measuring apparatus (SBW-330 manufactured by Kobelco Research Institute, Inc.). More specifically, 16 line segments were drawn on the front side 11a so as to pass the center of the plate-shaped workpiece (silicon wafer) 11 in such a manner that they were arranged at angularly equal intervals. On these 16 line segments, the height of the front side 11a was measured at plural points set at 1 mm intervals, and the difference between a maximum value and a minimum value for the height measured was calculated. Further, the size of waviness on the plate-shaped workpiece (silicon wafer) 11 was evaluated according to the curvature or density (darkness) of a saw mark formed in cutting the ingot into the silicon wafer. For example, in the case that the saw mark was dark to show the emphasis of unevenness, the size of waviness was determined to be large.

### Example A2

In Example A2, the content of each component of the composition A was set to 45% by mass for the (meth)acrylate having an urethane bond, 15% by mass for the (meth)acrylate not having an urethane bond, and 40% by mass for the plasticizer. As the (meth)acrylate not having an urethane bond, phenylglycidyl ether acrylate was used. The other configuration is the same as that of Example A1.

### Example A3

In Example A3, the content of each component of the composition A was set to 45% by mass for the (meth)acrylate having an urethane bond, 10% by mass for the (meth)acrylate not having an urethane bond, and 45% by mass for the plasticizer. As the (meth)acrylate not having an urethane bond, isobornyl acrylate was used. As the plasticizer, dimethyl phthalate was used. The other configuration is the same as that of Example A1.

### Example A4

In Example A4, the content of each component of the composition A was set to 40% by mass for the (meth)acrylate having an urethane bond, 10% by mass for the (meth)acrylate not having an urethane bond, and 50% by mass for the plasticizer. The other configuration is the same as that of Example A1.

### Example A5

In Example A5, the content of each component of the composition A was set to 40% by mass for the (meth)acrylate having an urethane bond, 5% by mass for the (meth)acrylate not having an urethane bond, and 55% by mass for the plasticizer. As the (meth)acrylate not having an urethane bond, isobornyl acrylate was used. As the plasticizer, dimethyl phthalate was used. The other configuration is the same as that of Example A1.

### Example A6

In Example A6, the content of each component of the composition A was set to 35% by mass for the (meth)acrylate having an urethane bond, 5% by mass for the (meth)acrylate not having an urethane bond, and 60% by mass for the plasticizer. As the plasticizer, dimethyl phthalate was used. The other configuration is the same as that of Example A1.

### Example A7

In Example A7, the content of each component of the composition A was set to 30% by mass for the (meth)acrylate having an urethane bond, 5% by mass for the (meth)acrylate not having an urethane bond, and 65% by mass for the plasticizer. As the (meth)acrylate not having an urethane bond, isobornyl acrylate was used. As the plasticizer, dimethyl phthalate was used. The other configuration is the same as that of Example A1.

### Example A8

In Example A8, the content of each component of the composition A was set to 20% by mass for the (meth)acrylate having an urethane bond, 0% by mass for the (meth)acrylate not having an urethane bond, and 80% by mass for the plasticizer. In other words, the composition A in Example A8 does not contain the (meth)acrylate not having an urethane bond, but contains only the (meth)acrylate having an urethane bond and the plasticizer. As the plasticizer, dimethyl phthalate was used. The other configuration is the same as that of Example A1.

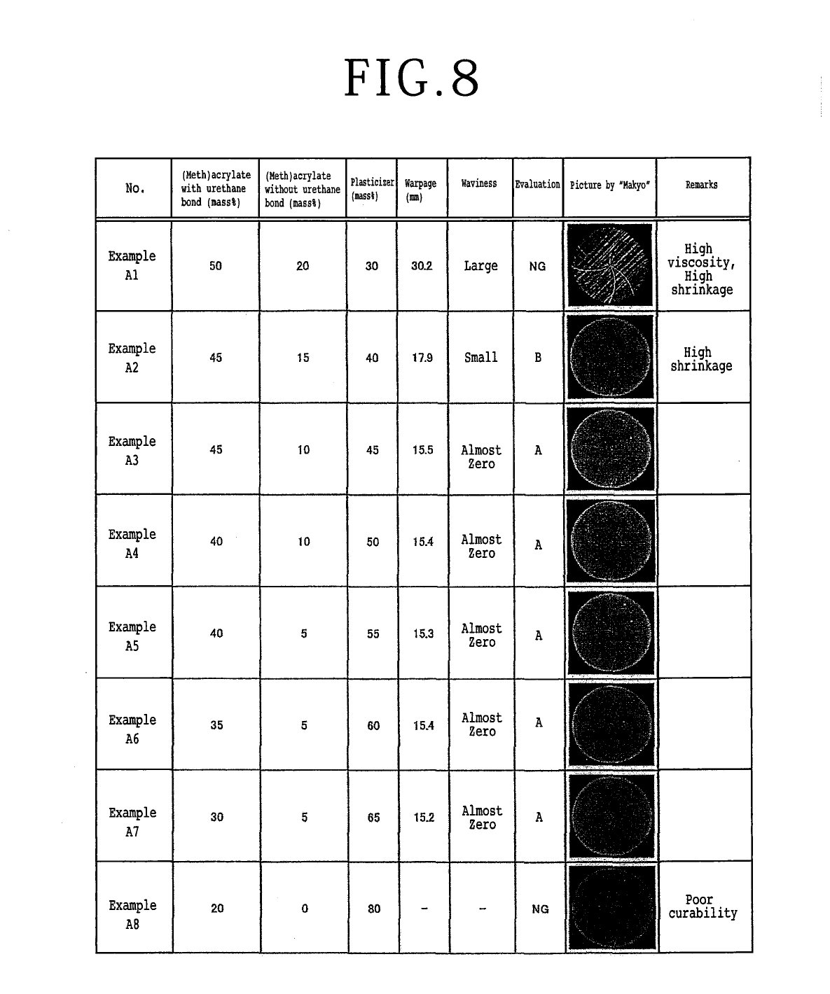

FIG. 8 is a table obtained by summarizing the results of Examples A1 to A8. In the column of “Evaluation” in FIG. 8, A indicates “good,” B indicates “acceptable,” and NG indicates “poor.” FIG. 8 also shows pictures of the surface condition of the plate-shaped workpiece 11 as taken by the surface defect inspecting apparatus. As shown in FIG. 8, in Example A1, the ratio of the plasticizer to the (meth)acrylate is low, so that the resin composition 15a before curing has high viscosity and high shrinkage. As a result, the amount of warpage after curing is large and the size of waviness is also large. This waviness also appears on the picture by “Makyo.”

In Example A8, the composition A is composed of 20% by mass of the (meth)acrylate having an urethane bond and 80% by mass of the plasticizer and does not contain the (meth)acrylate not having an urethane bond. As a result, the resin composition 15a cannot be sufficiently cured.

In contrast, in Examples A2 to A7, the content of the (meth)acrylate having an urethane bond falls within the range of 30% to 45% by mass, the content of the (meth)acrylate not having an urethane bond falls within the range of 5% to 15% by mass, and the content of the plasticizer falls within the range of 40% to 65% by mass. Under these conditions, the resin composition 15a can be properly cured and the warpage and waviness of the plate-shaped workpiece (silicon wafer) 11 can also be suppressed.

Thus, according to this preferred embodiment, the content of the (meth)acrylate having an urethane bond in the composition A is set to 30% to 45% by mass, the content of the (meth)acrylate not having an urethane bond in the composition A is set to 5% to 15% by mass, and the content of the plasticizer in the composition A is set to 40% to 65% by mass. With this configuration, the resin composition 15a can be properly cured and the shrinkage of the resin composition 15a in curing can also be suppressed. Accordingly, the warpage and waviness of the plate-shaped workpiece (silicon wafer) 11 can be suppressed. In particular, by setting the content of the (meth)acrylate having an urethane bond to 30% to 45% by mass, setting the content of the (meth)acrylate not having an urethane bond to 5% to 10% by mass, and setting the content of the plasticizer to 45% to 65% by mass, the warpage and waviness of the plate-shaped workpiece (silicon wafer) 11 can be further suppressed. Accordingly, the resin composition 15a of the first preferred embodiment can be cured in a short time with the shrinkage suppressed. As a result, a stress generated in the plate-shaped workpiece 11 in fixing it can be reduced and high productivity can be maintained.

The resin composition 15b of the second preferred embodiment will now be described. As compared with the resin composition 15a of the first preferred embodiment mentioned above, the resin composition 15b of the second preferred embodiment is largely different in the point that the (meth)acrylate not having an urethane bond (urethane group) is not used. The resin composition 15b of the second preferred embodiment includes a composition and a photopolymerization initiator added to this composition in a predetermined proportion (e.g., 1% to 5%) to the whole amount of this composition, wherein this composition (which will be hereinafter referred to as composition B) is composed of (meth)acrylate having an urethane bond (urethane group) and a reactive diluent. The content of the photopolymerization initiator is arbitrarily adjusted in such a range that curability of the resin composition 15b can be maintained.

The (meth)acrylate having an urethane bond (urethane group) has an urethane group in a molecule. Examples of the (meth)acrylate having an urethane bond include the following products, that is, Light acrylate IAA, AT-600, UA-306H, UA-306T, UA-306I, UA-510H, UF-8001G, DAUA-167, and UF-07DF (all manufactured by Kyoeisha Chemical Co., Ltd.); R-1235, R-1220, RST-201, RST-402, R-1301, R-1304, R-1214, R-1302XT, GX-8801A, R-1603, R-1150D, DOCR-102, and DOCR-206 (all manufactured by Dai-ichi Kogyo Seiyaku Co., Ltd.); and UX-3204, UX-4101, UXT-6100, UX-6101, UX-7101, UX-8101, UX-0937, UXF-4001-M35, UXF-4002, DPHA-40H, UX-5000, UX-5102D-M20, UX-5103D, UX-5005, UX-3204, UX-4101, UX-6101, UX-7101, UX-8101, UX-0937, UXF-4001-M35, UXF-4002, UXT-6100, DPHA-40H, UX-5000, UX-5102D-M20, UX-5103, and UX-5005 (all manufactured by Nippon Kayaku Co., Ltd.). In this preferred embodiment, UF-07DF (manufactured by Kyoeisha Chemical Co., Ltd.) is used as the (meth)acrylate having an urethane bond.

The reactive diluent functions to reduce the viscosity of the (meth)acrylate without damaging the characteristics thereof. Examples of the reactive diluent include glycidyl ether. In this preferred embodiment, 2-ethylhexyl glycidyl ether (Formula 1), p-sec-butylphenyl-glycidyl ether (Formula 2), or p-tert-butylphenyl-glycidyl ether (Formula 3) is used as the reactive diluent.

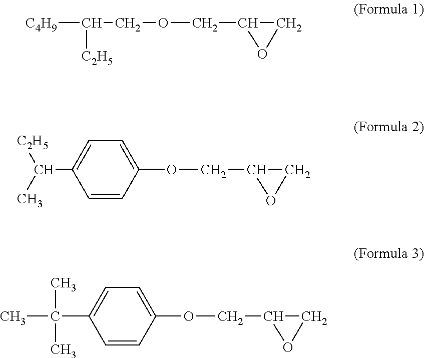

The glycidyl ether shown in each of Formula 1 to Formula 3 has a single epoxy group in a molecule. The reaction between the (meth)acrylate and the reactive diluent in this preferred embodiment includes that the epoxy group contained in the glycidyl ether as the reactive diluent is modified to give strong coupling between the (meth)acrylate having an urethane bond and the reactive diluent. The reaction between the (meth)acrylate and the reactive diluent further includes that the epoxy group is retained and the (meth)acrylate and the reactive diluent interact with each other.

The photopolymerization initiator functions to initiate the photopolymerization of the composition B composed of the (meth)acrylate having an urethane bond (urethane group) and the reactive diluent, by applying light (e.g., ultraviolet light). In this preferred embodiment, 1-hydroxy cyclohexyl phenyl ketone (e.g., Irgacure (registered trademark) 184 etc. manufactured by BASF) is used as the photopolymerization initiator.

The composition B in the resin composition 15b of the second preferred embodiment contains 35% to 70% by mass of the (meth)acrylate having an urethane bond and 30% to 65% by mass of the reactive diluent.

In general, the (meth)acrylate having an urethane bond shows high curability and low shrinkage in curing. However, since this (meth)acrylate has an urethane bond in a molecule, this (meth)acrylate has a large molecular weight and tends to have high viscosity. To cope with this problem, (meth)acrylate not having an urethane bond is usually mixed with the (meth)acrylate having an urethane bond because the (meth)acrylate not having an urethane bond has low viscosity with high shrinkage in curing. In the second preferred embodiment, the (meth)acrylate having an urethane bond and the reactive diluent having a single epoxy group in a molecule are mixed with each other to constitute the composition B, so that the content of the (meth)acrylate having an urethane bond in the composition B can be reduced. Further, as compared with a reactive diluent having plural epoxy groups in a molecule, the reactive diluent having a single epoxy group in a molecule can reduce the viscosity of the composition B. Thus, the composition B does not contain the (meth)acrylate not having an urethane bond, but contains the (meth)acrylate having an urethane bond and the reactive diluent having a single epoxy group in a molecule. With this configuration, the progress of reaction of epoxy resin can be suppressed and the reaction of the epoxy resin can be adjusted so that it does not completely proceed. Thus, in the second preferred embodiment, the viscosity of the composition B is suppressed and the content of the (meth)acrylate having an urethane bond in the composition B is reduced. Accordingly, the resin composition 15b of the second preferred embodiment can be cured in a short time by the application of ultraviolet light with the shrinkage suppressed. As a result, a stress generated in the plate-shaped workpiece 11 in fixing it can be reduced.

There will now be described examples of the composition B composed of the (meth)acrylate having an urethane bond and the reactive diluent, as prepared by making the content of each component different. That is, in the following examples, the content of each component of the composition B is changed to prepare a plurality of resin compositions.

### Example B1

In Example B1, a silicon wafer (as-sliced wafer) obtained by cutting an ingot was used as the plate-shaped workpiece 11. Further, the content of each component of the composition B was set to 70% by mass for the (meth)acrylate having an urethane bond and 30% by mass for the reactive diluent. As the (meth)acrylate having an urethane bond, UF-07DF (manufactured by Kyoeisha Chemical Co., Ltd.) was used. As the reactive diluent, 2-ethylhexyl-glycidyl ether was used. Further, as the photopolymerization initiator, 1-hydroxy cyclohexyl phenyl ketone was used and it was added in a proportion of 1% by mass to the whole amount of the composition B.

The resin composition 15b prepared above was used to fix the plate-shaped workpiece (silicon wafer) 11 in the following fixing method. That is, ultraviolet light is applied to the resin composition 15b for a predetermined period of time (one minute), thereby curing the resin composition 15b. By using a surface defect inspecting apparatus “Makyo” (YIS-300SP manufactured by Yamashita Denso Corporation), the surface condition of the plate-shaped workpiece 11 fixed to the resin composition 15b was checked. Further, after grinding the front side (second surface) 11a of the plate-shaped workpiece 11 fixed to the resin composition 15b and next removing the plate-shaped workpiece 11 from the resin composition 15b, the amount of warpage of the plate-shaped workpiece 11 and the size of waviness on the plate-shaped workpiece 11 were observed.

The amount of warpage of the plate-shaped workpiece 11 was evaluated by using a flatness measuring apparatus (SBW-330 manufactured by Kobelco Research Institute, Inc.). More specifically, 16 line segments were drawn on the front side 11a so as to pass the center of the plate-shaped workpiece (silicon wafer) 11 in such a manner that they were arranged at angularly equal intervals. On these 16 line segments, the height of the front side 11a was measured at plural points set at 1 mm intervals, and the difference between a maximum value and a minimum value for the height measured was calculated. Further, the size of waviness on the plate-shaped workpiece (silicon wafer) 11 was evaluated according to the curvature or density (darkness) of a saw mark formed in cutting the ingot into the silicon wafer. For example, in the case that the saw mark was dark to show the emphasis of unevenness, the size of waviness was determined to be large.

### Example B2

In Example B2, the content of each component of the composition B was set to 60% by mass for the (meth)acrylate having an urethane bond and 40% by mass for the reactive diluent. The other configuration is the same as that of Example B1.

### Example B3

In Example B3, the content of each component of the composition B was set to 50% by mass for the (meth)acrylate having an urethane bond and 50% by mass for the reactive diluent. The other configuration is the same as that of Example B1.

### Example B4

In Example B4, the content of each component of the composition B was set to 45% by mass for the (meth)acrylate having an urethane bond and 55% by mass for the reactive diluent. The other configuration is the same as that of Example B1.

### Example B5

In Example B5, the content of each component of the composition B was set to 40% by mass for the (meth)acrylate having an urethane bond and 60% by mass for the reactive diluent. The other configuration is the same as that of Example B1.

### Example B6

In Example B6, the content of each component of the composition B was set to 35% by mass for the (meth)acrylate having an urethane bond and 65% by mass for the reactive diluent. The other configuration is the same as that of Example B1.

### Example B7

In Example B7, the content of each component of the composition B was set to 30% by mass for the (meth)acrylate having an urethane bond and 70% by mass for the reactive diluent. The other configuration is the same as that of Example B1.

### (Reference)

In Reference, bisphenol A type epoxy resin was used as the reactive diluent. The bisphenol A type epoxy resin has two epoxy groups in a molecule as shown in Formula 4. The other configuration is the same as that of Examples B1 to B7.

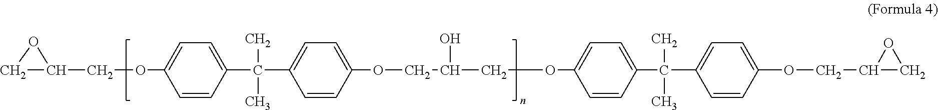

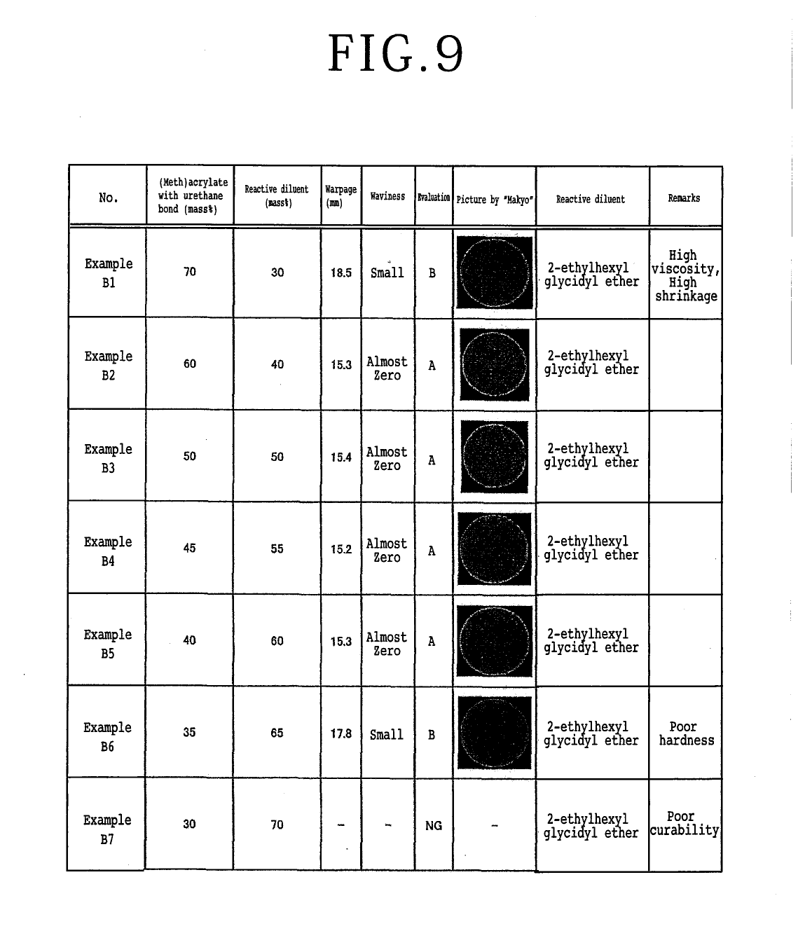

FIG. 9 is a table obtained by summarizing the results of Examples B1 to B7. In the column of “Evaluation” in FIG. 9, A indicates “good,” B indicates “acceptable,” and NG indicates “poor.” FIG. 9 also shows pictures of the surface condition of the plate-shaped workpiece 11 as taken by the surface defect inspecting apparatus. As shown in FIG. 9, in Example B7, the content of the (meth)acrylate is low, so that the resin composition 15b cannot be sufficiently cured.

In contrast, in Examples B1 to B6, the content of the (meth)acrylate having an urethane bond falls within the range of 35% to 70% by mass and the content of the reactive diluent falls within the range of 30% to 65% by mass. Under these conditions, the resin composition 15b can be properly cured and the warpage and waviness of the plate-shaped workpiece (silicon wafer) 11 can also be suppressed.

Although the evaluation of Examples B1 and B6 is “acceptable” on the basis of the warpage and waviness of the plate-shaped workpiece (silicon wafer) 11, these examples are inferior to the other examples (Examples B2 to B5) in the points that the shrinkage is higher (Example B1) and the hardness is lower (Example B6). Accordingly, by setting the content of the (meth)acrylate having an urethane bond to 40% to 60% by mass and setting the content of the reactive diluent to 40% to 60% by mass, the warpage and waviness of the plate-shaped workpiece (silicon wafer) 11 can be further suppressed. Accordingly, the resin composition 15b of the second preferred embodiment can be cured in a short time with the shrinkage suppressed. As a result, a stress generated in the plate-shaped workpiece 11 in fixing it can be reduced and high productivity can be maintained.

Although not shown in FIG. 9, in comparison with Reference using bisphenol A type epoxy resin having two epoxy groups in a molecule as the reactive diluent, the examples having a high content of reactive diluent (corresponding to Examples B5 to B7 having a single epoxy group in a molecule) are advantageous so that the generation of unreacted bonds can be suppressed to thereby reduce bleeding and accordingly improve the curability. Conversely, in the case that the content of the reactive diluent is low (corresponding to Examples B1 to B4 having a single epoxy group in a molecule), it is possible to suppress the tendency that the viscosity and shrinkage of the resin composition increase with a decrease in content of the reactive diluent as compared with Reference having two epoxy groups in a molecule. As a result, the warpage and waviness after curing can be suppressed.

As described above, the resin composition 15 according to this preferred embodiment is a resin composition for fixing the plate-shaped workpiece 11, and this resin composition includes a composition and a photopolymerization initiator added to this composition, wherein this composition (composition A or B) is composed of (meth)acrylate and a plasticizer or a reactive diluent. The shrinkage of the resin composition 15 in curing can be reduced by the plasticizer or the reactive diluent, so that it is possible to realize the resin composition 15 which can be cured in a short time with the shrinkage suppressed. Accordingly, it is possible to obtain the resin composition 15 which can reduce a stress generated in the plate-shaped workpiece 11 in fixing the plate-shaped workpiece 11.

Further, the composition A constituting the resin composition 15a of the first preferred embodiment contains 30% to 45% by mass of (meth)acrylate having an urethane bond, 5% to 15% by mass of (meth)acrylate not having an urethane bond, and 40% to 65% by mass of plasticizer, which is an ester. Thus, a plurality of materials are mixed in a proper proportion, so that it is possible to realize the resin composition 15a which can be cured in a short time with the shrinkage suppressed. Accordingly, it is possible to obtain the resin composition 15a which can reduce a stress generated in the plate-shaped workpiece 11 in fixing the plate-shaped workpiece 11.

Further, the composition B constituting the resin composition 15b of the second preferred embodiment contains 35% to 70% by mass of (meth)acrylate having an urethane bond and 30% to 65% by mass of reactive diluent, which is an ether having a single epoxy group in a molecule. Thus, a plurality of materials are mixed in a proper proportion, so that it is possible to realize the resin composition 15b which can be cured in a short time with the shrinkage suppressed. Accordingly, it is possible to obtain the resin composition 15b which can reduce a stress generated in the plate-shaped workpiece 11 in fixing the plate-shaped workpiece 11.

Further, the fixing method of fixing the plate-shaped workpiece 11 by using the resin composition 15 includes the resin composition supplying step of supplying the resin composition 15 between the stage 18 and the back side 11b of the plate-shaped workpiece 11, the pressing step of applying a pressure to the plate-shaped workpiece 11 in a direction from the front side 11a toward the back side 11b after performing the resin composition supplying step, thereby pressing the plate-shaped workpiece 11 against the stage 18 to uniformly spread the resin composition 15 over the back side 11b of the plate-shaped workpiece 11, and the curing step of applying light to the resin composition 15 after performing the pressing step, thereby curing the resin composition 15. Accordingly, it is possible to realize the fixing method of fixing the plate-shaped workpiece 11 by using the resin composition 15 which can reduce a stress generated in the plate-shaped workpiece 11 in fixing the plate-shaped workpiece 11 and can maintain high productivity.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A resin composition for fixing a plate-shaped workpiece, said resin composition comprising a composition and a photopolymerization initiator added to said composition, wherein said composition is composed of (meth)acrylate and a plasticizer or a reactive diluent.

2. The resin composition according to claim 1, wherein said (meth)acrylate includes first (meth)acrylate having an urethane bond and second (meth)acrylate not having said urethane bond, and said composition contains 30% to 45% by mass of said first (meth)acrylate, 5% to 15% by mass of said second (meth)acrylate, and 40% to 65% by mass of said plasticizer.

3. The resin composition according to claim 1, wherein said plasticizer is an ester.

4. The resin composition according to claim 1, wherein said (meth)acrylate is (meth)acrylate having an urethane bond, and said composition contains 35% to 70% by mass of said (meth)acrylate having said urethane bond and 30% to 65% by mass of said reactive diluent.

5. The resin composition according to claim 1, wherein said reactive diluent is an ether having a single epoxy group in a molecule.

6. A fixing method of fixing a plate-shaped workpiece by using a resin composition including a composition and a photopolymerization initiator added to said composition, said composition being composed of (meth)acrylate and a plasticizer or a reactive diluent, said fixing method comprising:
a resin composition supplying step of supplying said resin composition between a stage and a first surface of said plate-shaped workpiece;
a pressing step of applying a pressure to said plate-shaped workpiece in a direction from a second surface of said plate-shaped workpiece toward said first surface after performing said resin composition supplying step, thereby pressing said plate-shaped workpiece against said stage to uniformly spread said resin composition over said first surface of said plate-shaped workpiece; and
a curing step of applying light to said resin composition after performing said pressing step, thereby curing said resin composition.
